(19) United States
(12) Patent Application Publication
(10) Pub. No.: US 2005/0132950 A1
(43) Pub. Date: Jun. 23, 2005

(54) Method of growing aluminum-containing nitride semiconductor single crystal

(76) Inventors: Dong Joon Kim, Seoul (KR); Jeong Tak Oh, Suwon (KR)

Correspondence Address: LOWE HAUPTMAN GILMAN AND BERNER, LLP, 1700 DIAGONAL ROAD, SUITE 300 /310, ALEXANDRIA, VA, 22314, US

(21) Appl. No.: 10/853,235

(22) Filed: May 26, 2004

(30) Foreign Application Priority Data
Dec. 23, 2003 (KR) 2003-95170

(51) Int. Cl. C30B 23/00

(52) U.S. Cl. 117/84

(57) ABSTRACT

Disclosed herein is a method of growing a nitride semiconductor single crystal. The method comprises the steps of preparing a nitride seed layer on a substrate for growing a nitride single crystal, forming a stripe patterned dielectric mask on the nitride seed layer, and growing an Al-containing nitride single crystal on the nitride seed layer formed with the dielectric mask while inflowing Cl-based gas or Br-based gas.

### BACKGROUND OF THE INVENTION

1. Field of the Invention

The present invention relates to a method of growing a nitride semiconductor single crystal, and more particularly to a method of growing an Al-containing nitride semiconductor single crystal with a low crystal defect density using a lateral epitaxial overgrowth method (hereinafter also referred to as “LEO method”).

2. Description of the Related Art

In general, due to a property of emitting light in a wide wavelength range from visible light to ultraviolet light, a group III nitride semiconductor is in the spotlight as a material for a blue-green photo-device and for a visible and UV light emitting diode (LED), such as LEDs or laser diodes (LDs). With regard to this, in order to manufacture higher efficiency photo-devices, it is necessary to provide a technique for growing a high-grade single crystal thin film of the group III nitride semiconductor.

Meanwhile, as a substrate for the group III nitride semiconductor is not generally available in terms of lattice parameters and thermal expansion coefficients, there are many difficulties in growing the single crystal thin film itself. Generally, the group III nitride semiconductor is grown on a sapphire (Al₂O₃) substrate, which is a dissimilar substrate for the semiconductor single crystal, using a heteroepitaxy method employing a Metal Organic Chemical Vapor Deposition (MOCVD) process, a Molecular Beam Epitaxy (MBE) process, etc. However, even in case of the sapphire substrate, since it is difficult to directly grow the high grade group III nitride semiconductor single crystal for the differences in lattice parameters and in thermal expansion coefficients thereof, a two-step growing method comprising the step of growing a nucleation layer at a low temperature and the step of growing a single crystal at a high temperature is generally employed. It is reported, however, that crystal defects of about 10⁹˜10¹⁰ cm⁻² occur even when the group III nitride semiconductor single crystal is grown after forming the nucleation layer at a low temperature on the sapphire substrate using the two-step growth method.

Recently, as a method for reducing the crystal defects in the group III nitride semiconductor, a lateral epitaxial overgrowth (LEO) method has been used. In this method, dislocations created at the interface between the different materials spread in the direction of crystal growth, howerver the portion of the crystal grown under the LEO method forms a high-grade single crystal. The method of growing the nitride semiconductor single crystal using the LEO method is shown in FIGS. 1a to 1d.

First, as shown in FIG. 1a, a GaN buffer layer 13 is grown on a sapphire substrate 11 and a stripe patterned dielectric mask 15 is formed on the GaN buffer layer. This dielectric mask 15 can be formed by depositing dielectric materials, such as SiO₂ and Si₃N₄, on the GaN buffer layer and by repeatedly patterning a stripe shape on the mask using a photolithography process.

Then, as a process of growing the nitride single crystal starts to be applied on the GaN buffer layer 13 formed with the dielectric mask 15 using the LEO method, as shown in FIG. 1b, a nitride single crystal 17′ is grown only in a window region between the masks 15.

If the nitride single crystal 17′ becomes higher than the dielectric mask 15, as shown in FIG. 1c, the nitride single crystal 17″ grows laterally over the dielectric mask 15, and finally, as shown in FIG. 1d, the nitride single crystal 17 is formed over the dielectric mask 15 by the lateral growth thereof.

As described above, even though the buffer layer 13 is used, the dislocations originating from defects created between the buffer layer 13 and the sapphire substrate 11 propagate in the direction of the growth. However, since the portion of the single crystal 17b grown by the LEO method grows in the parallel direction different from the direction of the dislocation movement, almost all of the dislocations do not propagate. As a result, in comparison with the single crystal 17a between the masks 15, the single crystal 17b on the dielectric mask pattern is formed as a excellent single crystal and there is provided an effect of reducing the crystal defect density to <10⁸ cm⁻².

However, even though the LEO method is used, it is difficult to grow an Al-containing nitride single crystal, such as AlGaN, to a low-defect, high-grade single crystal. This is because Al elements are very reactive with the dielectric mask, such as SiO₂ or Si₃N₄, and because crystals are grown on the dielectrics for a low surface mobility of Al ad-atoms. Thus, as shown in FIG. 1b, the Al-containing nitride is formed as polycrystals at the portion 17b in contact with the dielectric mask, resulting in a difficulty in growing a high-grade crystal.

As such, conventionally, there has been no provision suitable for growing the Al-containing nitride semiconductor, such as AlGaN, to be the low-defect, high-grade single crystal.

### SUMMARY OF THE INVENTION

The present invention has been made in view of the above problems, and it is an object of the present invention to provide a method of growing an Al-containing nitride single crystal with a lateral epitaxial overgrowth method, which consistently removes polycrystals created on a dielectric mask pattern by inflowing a predetermined etching gas into a reaction chamber.

In accordance with an aspect of the present invention, the above and other objects can be accomplished by the provision of a method of growing a nitride semiconductor single crystal, comprising the steps of: a) forming a nitride seed layer on a substrate for growing a nitride single crystal; b) forming a stripe patterned dielectric mask on the nitride seed layer; and c) growing an Al-containing nitride single crystal on the nitride seed layer formed with the dielectric mask, while inflowing Cl-based gas or Br-based gas.

The nitride seed layer may comprise a low temperature nucleation layer which can be used as a buffer layer, or may comprise a crystal layer satisfying the formula AlₓIn_{y}Ga_{(1-x-y)}N (where 0≦x≦1, 0≦y≦1, 0≦x+y≦1). Further, the dielectric mask of the present invention may comprise SiO₂ or Si₃N₄.

The Br-based gas or the Cl-based gas, which is an etching gas for removing polycrystals formed on the dielectric mask, may comprise at least one selected from the groups of Br₂, Cl₂, CBr₄, CCl₄, HBr and HCl.

Specifically, the Al-containing nitride semiconductor single crystal of the present invention may comprise AlGaN having a wide energy band gap. Further, the method of growing the low-defect single crystal of the present invention may be employed as a method for manufacturing a nitride semiconductor light emitting device containing Al which is used for sources of UV light and visible light, as is used in an AlGaN light emitting diode.

### BRIEF DESCRIPTION OF THE DRAWINGS

The foregoing and other objects and features of the present invention will be more clearly understood from the following detailed description taken in conjunction with the accompanying drawings, in which:

FIGS. 1a to 1d are sectional views showing a flow diagram for illustrating a conventional method of growing a nitride semiconductor single crystal;

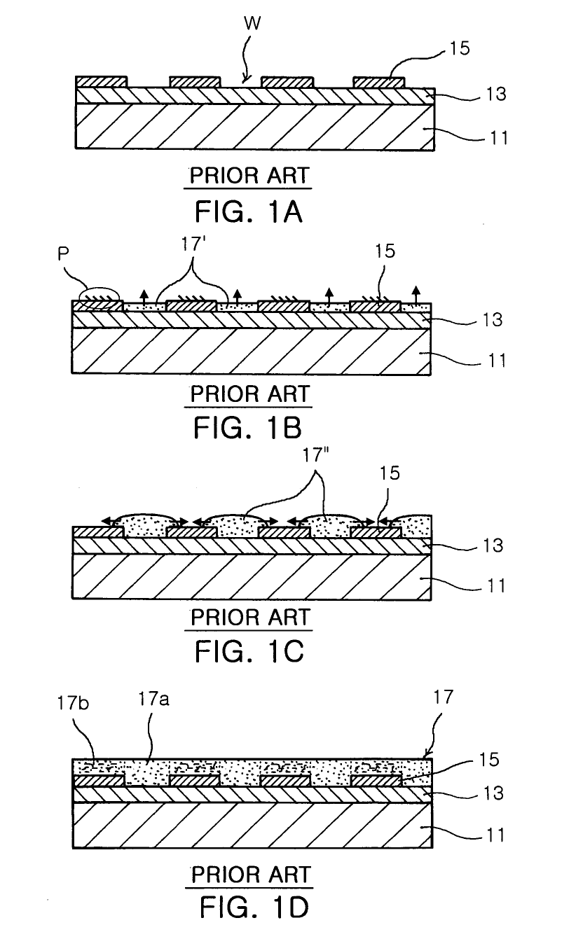

FIG. 2 is a flow chart illustrating a method of growing a nitride semiconductor single crystal according to an embodiment of the present invention; and

FIGS. 3a to 3d are sectional views showing a flow diagram for illustrating the method of growing a nitride semiconductor single crystal according to an embodiment of the present invention.

### DESCRIPTION OF THE PREFERRED EMBODIMENTS

Preferred embodiments will now be described in detail with reference to the accompanying drawings.

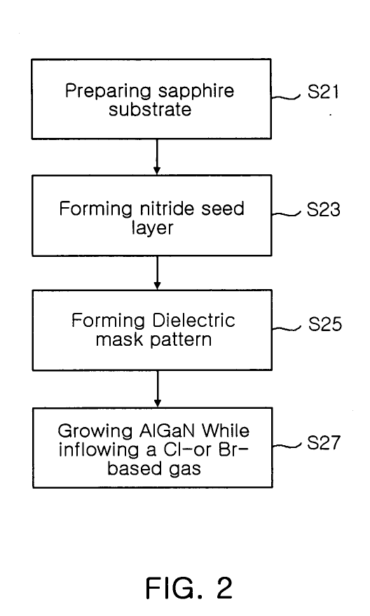

FIG. 2 is a flow chart illustrating a method of growing a nitride semiconductor single crystal according to an embodiment of the present invention.

First, the method of growing the nitride semiconductor single crystal according to the present invention starts from step S21. Besides a sapphire substrate, other substrates, such as a SiC substrate or a similar kind of nitride single crystal substrate, for growing a nitride single crystal can be utilized.

Subsequently, at step S23, a nitride seed layer, such as a GaN buffer layer, is grown on the sapphire substrate. The nitride seed layer is a layer acting as a buffer layer for growing a high-grade nitride crystal layer. For instance, it may comprise a low temperature nucleation layer, such as GaN or AlN, or comprise a crystal layer satisfying the formula AlₓIn_{y}Ga_{(1-x-y)}N (where 0≦x≦1, 0≦y≦1, 0≦x+y≦1).

At step S25, a dielectric mask having a stripe shape is formed on the nitride seed layer. The dielectric mask may comprise typical dielectric materials, such as SiO₂ or Si₃N₄, and can be obtained through a process for depositing the dielectric layer over the entire nitride seed layer and a selective etching process using a photolithography process.

At step S27, an Al-containing nitride single crystal is grown on the nitride seed layer formed with the dielectric mask using a lateral epitaxial overgrowth (LEO) method, while inflowing a Cl-based gas or a Br-based gas. Under the condition of the LEO method, when the Al-containing nitride single crystal layer, which is growing on the nitride seed layer between the masks, is grown to a height of the dielectric mask, the nitride single layer grows laterally over the dielectric mask, during which polycrystals created on the dielectric mask due to Al can be removed using the Cl-based gas or the Br-based gas.

According to the present invention, as the desired lateral growth process can be executed on the dielectric mask from which the polycrystals due to the Al element are removed by the process of inflowing the etching gas, the Al-containing nitride single crystal on the dielectric mask can be grown as a high-grade single crystal with a significantly reduced defect density by the lateral growth process.

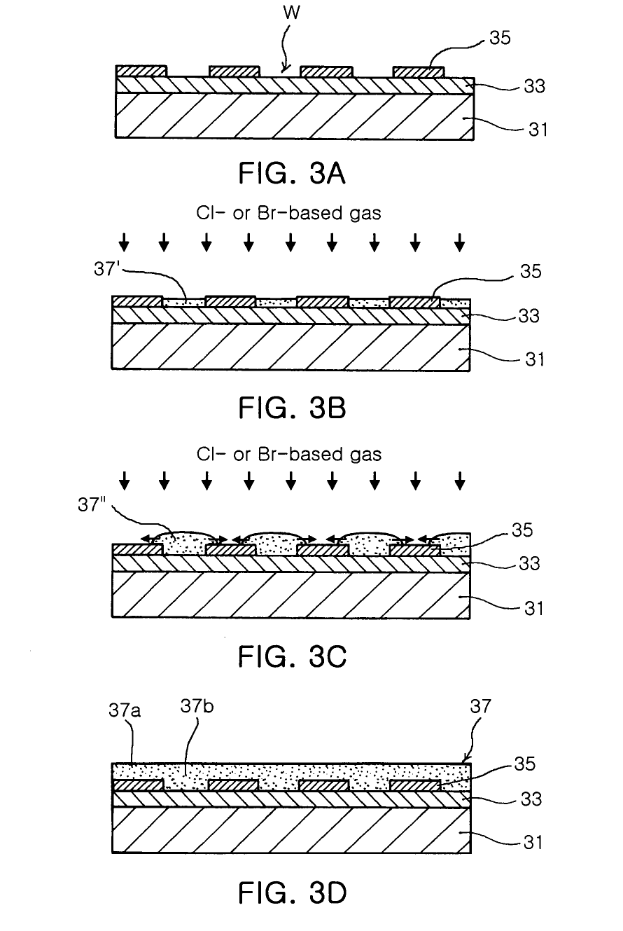

FIGS. 3a to 3d show sectional views of a flow diagram illustrating the method of growing the single crystal according to the embodiment of the present invention.

At first, as shown in FIG. 3a, a nitride seed layer 33 is grown on a sapphire substrate 31 and a dielectric mask 35 with a stripe shape is formed thereon. The nitride seed layer 33 is a layer acting as a buffer layer for growing a high-grade nitride crystal layer. For instance, it may comprise a low temperature nucleation layer or a crystal layer satisfying the formula AlₓIn_{y}Ga_{(1-x-y)}N (where 0≦x≦1, 0≦y≦1, 0≦x+y≦1). The dielectric mask 35 can be formed by depositing the dielectric layer on the nitride seed layer 33 and then by selectively etching the dielectric layer using a photolithography process.

Subsequently, Al-containing nitride single crystals (37′, 37″) are grown on the nitride seed layer 33 formed with the dielectric mask 35 using the LEO method, while inflowing the Cl-based gas or the Br-based gas. As shown in FIG. 3b, the Al-containing nitride single crystal (37′) is grown only in a window range between the dielctric masks 35, and as shown in FIG. 3c, the Al-containing nitride single crystal (37″), which is grown to a height of the dielectric mask 35, begins to grow laterally over the dielectric mask 35.

In the LEO method, since the Al elements have a high reactivity with the dielectric materials and a low surface mobility of the ad-atoms, Al remains in the dielectric mask 35 to form polycrystals. Since the polycrystals prevent the high-grade crystal to be grown on the dielectric mask 25, the present invention removes the polycrytals caused by the Al elements on the dielectric mask 35 using the Cl-based gas or Br-based gas, thereby providing a desired high-grade nitride crystal. In the present invention, the Br-based gas or the Cl-based gas comprises at least one selected from the groups of Br₂, Cl₂, CBr₄, CCl₄, HBr and HCl, and has a high etching rate to the Al-containing polycrystals.

Further, the process of inflowing the Cl-based gas or the Br-based gas is preferably carried out until the LEO method is completed. However, it is sufficient to carry out the process of inflowing the etching gas until the dielectric mask is completely covered with the nitride single crystal which is laterally grown.

Finally, referring to FIG. 3d, the nitride single crystal 37 completing the lateral growth to the upper side of the dielectric mask 35 is shown. In the portion of the Al-containing nitride single crystal layer 37a grown on the regions of the nitride seed layer between the dielectric masks, some dislocations are created at the interface due to lattice mismatching, while in the portion of the Al-containing nitride single crystal layer 37a formed on the dielectric mask, few of the dislocations created by the lateral growth spread and the growth process is undertaken in the state that the polycrystals due to Al are removed, so that the desired high-grade crystal can be grown.

The Al-containing nitride semiconductor, specifically AlₓIn_{y}Ga_{(1-x-y)}N, is a material having a wide energy band gap and is mainly used for manufacturing a large-output UV light emitting diode or a laser diode which is in the spotlight, recently. Since defects in the crystal cause deterioration in the optical efficiency of such a photo-device that is produced using the crystal, the method of growing the crystal growth of the present invention can be useful for producing the large-output UV photo-devices.

### EXAMPLE

An experiment was executed under the following conditions in order to ensure an excellent crystallinity in an Al-containing nitride single crystal manufactured according to the present invention.

At first, a GaN thin film with a thickness of 2 μm was grown on a sapphire substrate in a reaction chamber for the MOCVD process by supplying trimethylgallium and ammonia (NH3) with a current of 50 sccm and 7 slm, respectively, under the conditions of a pressure of 500 mbar and a temperature of 1190° C.

Then, after a SiO₂ dielectric layer with a thickness of 2 μm was deposited on the GaN thin film, a dielectric mask was prepared by patterning the mask and a window region between the masks to have a width of 9 μm and 3 μm, respectively.

Subsequently, using the MOCVD process, an Al-containing nitride single crystal, which is an Al_{0.1}Ga_{0.9}N crystal, is formed on the GaN thin film formed with the dielectric mask.

In order to satisfy the lateral epitaxial overgrowth conditions, the conditions for growing the Al_{0.1}Ga_{0.9}N crystal were adjusted as follows. That is, a pressure in the reaction chamber was 200 mbar at the same temperature. Trimethylgallium and trimethylaluminum were supplied with a current of 50 sccm and 10 sccm, respectively, under the same ammonia inflowing condition. The CBr₄ gas with a current of 600 sccm was also mixed into the chamber as an etching gas for removing the polycrystal layer caused by Al.

The state of the crystal on the dielectric mask in the resultant Al_{0.1}Ga_{0.9}N crystal was examined, and it was found that the defect density in the crystal according to the example was 1.2×10⁸ cm⁻². It was considerably low compared with the density of the defects (about 10⁹˜10¹⁰ cm⁻²) which can occur in the conventional growth method, not in the LEO method. The result confirms that a high-grade single crystal layer is formed using the LEO growth along with removing the polycrystals caused by the Al elements.

As apparent from the above description, in accordance with the present invention, bad influences (for example, formation of polycrystals) on the crystal growth due to the Al elements on the dielectric mask can be avoided by inflowing the Cl-based gas or the Br-based gas. Thus, the Al-containing nitride single crystal to be used as a UV photo-device can be grown to a high-grade, low-defect single crystal layer using the LEO method.

It should be understood that the embodiments and the accompanying drawings as described above have been described for illustrative purposes and the present invention is limited by the following claims. Further, those skilled in the art will appreciate that various modifications, additions and substitutions are allowed without departing from the scope and spirit of the invention as set forth in the accompanying claims.

1. A method of growing a nitride semiconductor single crystal, comprising the steps of:
a) forming a nitride seed layer on a substrate for growing a nitride single crystal;
b) forming a stripe patterned dielectric mask on the nitride seed layer; and
c) growing an Al-containing nitride single crystal on the nitride seed layer formed with the dielectric mask while inflowing Cl-based gas or Br-based gas.

2. The method as set forth in claim 1, wherein the nitride seed layer comprises a low temperature nucleation layer.

3. The method as set forth in claim 1, wherein the nitride seed layer comprises a crystal layer satisfying the formula AlₓIn_{y}Ga_{(1-x-y)}N (where 0≦x≦1, 0≦y≦1, 0≦x+y≦1).

4. The method as set forth in claim 1, wherein the dielectric mask comprises SiO₂ or Si₃N₄.

5. The method as set forth in claim 1, wherein the Br-based gas or the Cl-based gas comprises at least one selected from the groups of Br₂, Cl₂, CBr₄, CCl₄, HBr and HCl.

6. The method as set forth in claim 1, wherein the Al-containing nitride single crystal comprises AlGaN.

7. A method of manufacturing a nitride semiconductor light emitting device, comprising a method as set forth in claim 1.
